(19) United States
(12) Patent Application Publication
(10) Pub. No.: US 2013/0140440 A1
(43) Pub. Date: Jun. 6, 2013

(54) PHOTOELECTRIC CONVERTING APPARATUS

(71) Applicant: CANON KABUSHIKI KAISHA, Tokyo (JP)

(72) Inventor: Hideo Kobayashi, Tokyo (JP)

(73) Assignee: CANON KABUSHIKI KAISHA, Tokyo (JP)

(21) Appl. No.: 13/686,319

(22) Filed: Nov. 27, 2012

(30) Foreign Application Priority Data
Dec. 1, 2011 (JP) 2011-263704
Sep. 14, 2012 (JP) 2012-203185

(51) Int. Cl. H01L 31/02

(52) U.S. Cl. CPC H01L 31/02002
USPC 250/208.2; 250/214 AG

(57) ABSTRACT

A photoelectric converting apparatus has: a first photoelectric conversion element for outputting a current to a first terminal by a photoelectric conversion; a first detecting unit for detecting an electric potential of the first terminal of the first photoelectric conversion element; a first feedback unit for feeding back a signal based on the electric potential detected by the first detecting unit to the first terminal of the first photoelectric conversion element and output a current based on the electric potential of the first terminal of the first photoelectric conversion element to a first current output terminal; and a current supplying unit for supplying the current to the first terminal of the first photoelectric conversion element.

### BACKGROUND OF THE INVENTION

1. Field of the Invention

The present invention relates to a photoelectric converting apparatus.

2. Description of the Related Art

Japanese Patent Application Laid-Open No. 2000-077644 discloses a photoelectric converting apparatus using a phototransistor and a feedback unit. The photoelectric converting apparatus constructs a source grounding circuit by a constant current source and a MOSFET which is driven by the constant current source. A base potential of the phototransistor is decided by a voltage between a gate and a source of the MOSFET. In the photoelectric converting apparatus, when a light amount changes, since a collector current of the phototransistor changes, a voltage between a base and an emitter of the phototransistor changes. However, at this time, an emitter potential instead of the base potential of the phototransistor fluctuates mainly. Instead of the potential of the base which has been biased by a photocurrent, the potential of the emitter which has been biased by a larger current (˜hFE×photocurrent) is made to fluctuate, thereby improving light response performance. That is, a time which is required until the change in base potential and the change in emitter potential are completed after the light amount changed is shortened.

It is an object of the invention to provide a photoelectric converting apparatus having good light response performance.

### SUMMARY OF THE INVENTION

According to an aspect of the invention, there is provided a photoelectric converting apparatus comprising: a first photoelectric conversion element for outputting a current to a first terminal by a photoelectric conversion; a first detecting unit configured to detect an electric potential of the first terminal of the first photoelectric conversion element; a first feedback unit configured to feed back a signal based on the electric potential detected by the first detecting unit to the first terminal of the first photoelectric conversion element and output a current based on the electric potential of the first terminal of the first photoelectric conversion element to a first current output terminal; and a current supplying unit configured to supply the current to the first terminal of the first photoelectric conversion element.

Further features of the present invention will become apparent from the following description of exemplary embodiments with reference to the attached drawings.

### BRIEF DESCRIPTION OF THE DRAWINGS

FIG. 1 is a conceptual diagram illustrating operation points of a source grounding circuit.

FIG. 2 is a diagram illustrating an example of a construction of the first embodiment.

FIG. 3 is a diagram illustrating an example of the construction of the first embodiment.

FIG. 4 is an explanatory diagram of the first embodiment.

FIG. 5 is a diagram illustrating an example of a construction of the second embodiment.

FIG. 6 is a diagram illustrating an example of the construction of the second embodiment.

FIG. 7 is a diagram illustrating an example of a construction of the third and fourth embodiments.

FIG. 8 is a diagram illustrating an example of a construction of the fifth embodiment.

FIG. 9 is a diagram illustrating an example of the construction of the fifth embodiment.

FIG. 10 is a diagram illustrating an example of a construction of the sixth embodiment.

FIG. 11 is a diagram illustrating an example of a construction of the seventh embodiment.

FIG. 12 is a diagram illustrating an example of a construction of the eighth embodiment.

FIG. 13 is a diagram illustrating an example of the construction of the eighth embodiment.

FIG. 14 is a diagram illustrating an example of a construction of the ninth embodiment.

FIG. 15 is a diagram illustrating an example of a construction of the tenth embodiment.

FIG. 16 is a diagram illustrating an example of a construction of the eleventh embodiment.

FIG. 17 is a diagram illustrating an example of a construction of the twelfth embodiment.

FIG. 18 is a diagram illustrating an example of a construction of the thirteenth embodiment.

### DESCRIPTION OF THE EMBODIMENTS

### First Embodiment

FIG. 2 is a diagram illustrating an example of a construction of a photoelectric converting apparatus (sensor) according to the first embodiment. The photoelectric converting apparatus has: a first photoelectric conversion element 10; a first terminal 20 to which a photocurrent generated from the first photoelectric conversion element 10 is input; a first detecting unit 30; a first feedback unit 40; a current supplying unit 50; and a first current output terminal 60. The photoelectric conversion element 10 outputs a current to the terminal 20 by the photoelectric conversion. The detecting unit 30 detects an electric potential of the terminal 20 of the photoelectric conversion element 10. The feedback unit 40 feeds back a feedback signal based on the electric potential detected by the detecting unit 30 to the terminal 20 of the photoelectric conversion element 10 and outputs the current based on the electric potential of the terminal of the photoelectric conversion element 10 to the current output terminal 60. The current supplying unit 50 supplies the current to the terminal 20 of the photoelectric conversion element 10. In FIG. 2, the electric potential of the terminal 20 to which the photocurrent is input is detected by the detecting unit 30 and is fed back by using the feedback unit 40, thereby enabling a fluctuation of the electric potential of the terminal 20 at the time when the photocurrent is changed to be reduced.

In the embodiment, by supplying the current to the terminal 20 from the current supplying unit 50, the light response performance can be improved.

FIG. 3 is a diagram illustrating an example of a specific circuit construction of the photoelectric converting apparatus in FIG. 2. First, a correspondence between FIGS. 2 and 3 will be described. The first photoelectric conversion element 10 is a first photodiode for performing the photoelectric conversion. The first terminal 20 of the first photoelectric conversion element is an anode of the first photodiode. The first detecting unit 30 has a first field effect transistor (MOSFET) 100 and a first current source (constant current source) 90. The first feedback unit 40 has a first bipolar transistor 80 and a second field effect transistor (MOSFET) 70. The anode 20 of the photodiode 10 is connected to a gate of the first field effect transistor 100 and a base of the bipolar transistor 80. A cathode of the photodiode 10 is connected to a power voltage terminal 120. A source of the first field effect transistor 100 is connected to the power voltage terminal 120 and a drain is connected to a ground terminal through the first current source 90. A source of the second field effect transistor 70 is connected to an emitter of the bipolar transistor 80, a gate is connected to the drain of the first field effect transistor 100, and a drain is connected to the current output terminal 60. A collector of the bipolar transistor 80 is connected to the power voltage terminal 120. The current supplying unit 50 has a second current source 110 and is connected between the power voltage terminal 120 and the anode 20 of the photodiode 10. The detecting unit 30 is constructed by a source grounding circuit of the constant current source 90 and the MOSFET 100. The power voltage terminal 120 is connected to a power source V_{cc}. In the embodiment, when the photocurrent at the terminal 20 is equal to or less than a predetermined value, by supplying a predetermined current from the current source 110 to the terminal 20, the current of the terminal 20 can be held to be constant, so that the potential fluctuation of the terminal 20 can be suppressed. For example, the fluctuation of the electric potential of the terminal 20 in the case where the state was changed from an exposure state to a dark state before the start of the detecting operation in which the photocurrent is equal to or less than the predetermined value can be further reduced. Thus, a time that is required to charge the capacitor associated with the base by using the current of the terminal 20 at the time of starting the detecting operation can be shortened. Consequently, the light response performance in the case where the photocurrent is small can be improved.

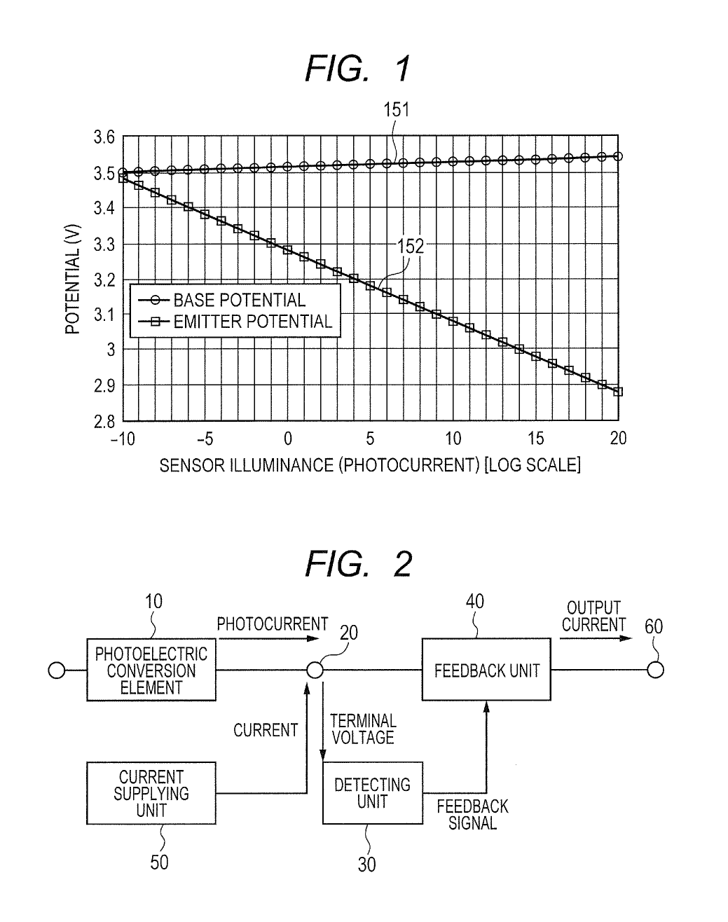

In FIG. 3, when there is no current source 110, the base potential and the emitter potential of the bipolar transistor 80 changes as illustrated in FIG. 1 in accordance with sensor illuminance (or photocurrent value of the photoelectric conversion element 10). FIG. 1 is a conceptual diagram illustrating operation points of the source grounding circuit. An axis of abscissa indicates a light amount (or photocurrent=base current). The axis of abscissa indicates a log scale. The light amount is doubled every scale. An axis of ordinate indicates an electric potential. It will be understood that the voltage between the base and the emitter increases linearly to an exponential functional increase of the light amount. This is because a relation expressed by the following equation (1) is satisfied between a voltage V_{be} between the base and the emitter and a collector current I_{c}.

I_{c}=Iₛ×exp(qV_{be}/kT) (1)

Where, Iₛ denotes a saturation current, q an elementary electric charge, k a Boltzmann's constant, and T an absolute temperature.

When the light amount increases, since a base potential 151 increases slightly, an output of the source grounding circuit decreases, so that an emitter potential 152 decreases. Therefore, when the light amount changes, a slight fluctuation occurs also in the base potential 151. It is now assumed that a range of the light amount to be detected by the photoelectric conversion element 10 is a range of scales 0 to 20 of the axis of abscissa in FIG. 1. If the state before the start of the detecting operation is a state (for example, in an almost light shielding state, the scale of the axis of abscissa is equal to −10) which is darker than it, the base potential 151 decreases unnecessarily. When the state is set to the exposure state again from such a state and the light (the light amount lies within the range of scales 0 to 20 of the axis of abscissa in FIG. 1) is irradiated and the detecting operation is started, the capacitor associated with the base is charged by the photocurrent. Therefore, it is necessary to raise the base potential 151 from the base potential 151 of the scale −10 to the base potential 151 of the scale 0. As shown in this example, even if the fluctuation, that is, decrease amount of the base potential 151 is very small, if the photocurrent for charging the capacitor associated with the base in order to raise the decrease amount is small, there is such a problem that it takes a time for the raising operation and the light response performance deteriorates.

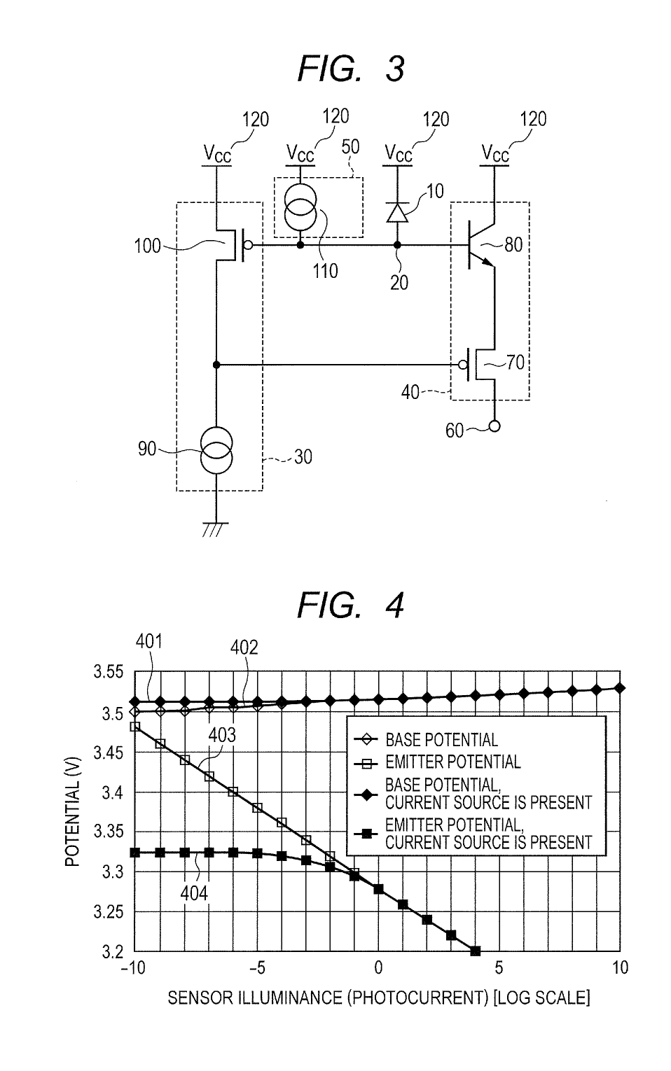

An example of a current change in the case where the current is supplied from the current source 110 in FIG. 3 is illustrated in FIG. 4. In FIG. 4, an axis of abscissa and an axis of ordinate are enlargedly shown as compared with those of FIG. 1. A base potential 402 is a base potential of the bipolar transistor 80 in the case where the current source 110 is absent. An emitter potential 403 is an emitter potential of the bipolar transistor 80 in the case where the current source 110 is absent. A base potential 401 is a base potential of the bipolar transistor 80 in the case where the current source 110 is present. An emitter potential 404 is an emitter potential of the bipolar transistor 80 in the case where the current source 110 is present. FIG. 4 illustrates a case where a value of the current which is supplied from the current source 110 is almost equal to a value of the photocurrent which is generated in the photoelectric conversion element 10 in FIG. 3 at the time of the light amount in which the scale of the axis of abscissa in FIG. 4 is equal to −3. A reason why current − voltage characteristics at the time when the current source 110 is present change as illustrated in FIG. 4 will now be described.

In FIG. 3, the collector current I_{c} of the bipolar transistor 80 is expressed by the following equation (2).

I_{c}=hFE×(Iₛᵤₚ+Iₚ) (2)

Where, hFE denotes a current amplification factor of the bipolar transistor 80, Iₚ a photocurrent of the photoelectric conversion element 10, and Iₛᵤₚ a current value of the current source 110.

The following equation (3) can be derived from the equations (1) and (2).

hFE×(Iₛᵤₚ+Iₚ)=Iₛ×exp(qV_{be}/kT) (3)

From the equation (3), a decrease amount of the voltage V_{be} between the base and the emitter in the case where the photocurrent Iₚ of the photoelectric conversion element 10 in FIG. 3 is reduced to the half, that is, in the case where the illuminance of the sensor of the axis of abscissa in FIG. 4 has temporarily decreased can be estimated. In the equation (3), a reduction amount ΔV_{be} of the voltage V_{be} in the case where the photocurrent Iₚ is reduced to Iₚ/2 is obtained by the following equation (4).

$$Δ {V}_{be} = \frac{kT}{q} \times ln \{ \frac{( {I}_{p} + {I}_{sup} )}{( \frac{{I}_{p}}{2} + {I}_{sup} )} \} \qquad ( 4 )$$

In the equation (4), if Iₛᵤₚ can be ignored for Iₚ, the following expression (5) is satisfied.

$$Δ {V}_{be} \approx \frac{k T}{q} \times ln ( 2 ) \qquad ( 5 )$$

In FIG. 4, for example, when the sensor illuminance of the axis of abscissa decreases from the scale 4 to the scale 3, since the current Iₛᵤₚ (the scale of the axis of abscissa corresponds to −3) in the equation (4) is equal to up to a value of Iₚ/2⁷, the current Iₛᵤₚ can be ignored. Thus, the reduction amount ΔV_{be} of the base-emitter voltage V_{be} is as shown by the expression (5). This result is equivalent to that in the case of FIG. 1. However, in a region of a further low illuminance, in the equation (4), if the current Iₛᵤₚ enters a region where it cannot ignored, the reduction amount ΔV_{be} of the base-emitter voltage V_{be} becomes a value smaller than that obtained in the expression (5). That is, in FIG. 4, even if the sensor illuminance of the axis of abscissa decreased by one scale, the base-emitter voltage V_{be} does not change so much. Further, in the low illuminance region, in the equation (4), on the contrary, in a region where the photocurrent Iₚ is equal to such a value that can be ignored to the current Iₛᵤₚ, ΔV_{be}=0 and the base-emitter voltage V_{be} does not change. Finally, the base-emitter voltage V_{be} becomes constant in the following expression (6) from the equation (3).

$${V}_{be} \approx \frac{kT}{q} \times ln ( \frac{h FE \times {I}_{sup}}{{I}_{s}} ) \qquad ( 6 )$$

It will be understood that by adding the current supplying unit 50 and using the current source 110 as a current supplying unit 50 in this manner, ordinarily, a change amount of the base potential in the case where the sensor illuminance changes to, for example, the scale 0 on the axis of abscissa in FIG. 4 from the state which is darker than the range where the light amount is detected has decreased. Thus, the time which is required to charge the capacitor associated with the base in order to raise the base potential can be shortened. Therefore, the light response performance can be improved.

As mentioned above, by providing the second current source 110 as a current supplying unit 50 for the terminal 20 of the photoelectric conversion element 10, the potential fluctuation of the terminal 20 due to the light amount fluctuation can be suppressed and the photoelectric converting apparatus having the good light response performance can be provided.

The case where the current value of the current source 110 is equal to the scale −3 on the axis of abscissa in FIG. 4 has been described above as an example. Assuming that the minimum illuminance which is detected by the sensor is equal to the scale 0 on the axis of abscissa in FIG. 4, this means that at the time of the minimum illuminance, an error current of ⅛ of the photocurrent is generated from the current source 110. Therefore, although it is desirable to increase the current of the current source 110 from a viewpoint of decreasing the reduction amount of the base potential, it is desirable not to excessively increase such a current from a viewpoint of an S/N ratio. The optimum current value is decided in consideration of a trade-off between both of them.

### Second Embodiment

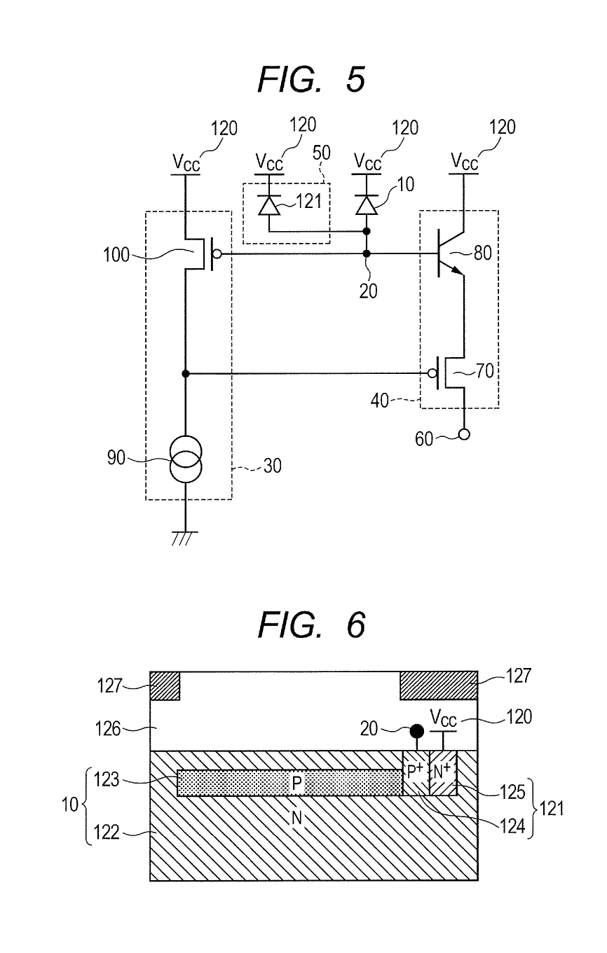

A photoelectric converting apparatus according to the second embodiment will now be described with reference to FIGS. 5 and 6. The embodiment will be described hereinbelow with respect to only points different from the first embodiment. The current supplying unit 50 has a diode 121. The diode 121 supplies a current to the terminal 20 by a leak current. FIG. 6 illustrates an example of a cross sectional structure of the photoelectric conversion element 10 and the diode 121. In FIG. 6, a P-type region 123, a contact portion 124, and an N-type contact portion 125 are formed in an N-type region 122. An interlayer insulating film 126 and a light shielding film 127 are provided. In FIG. 6, the photoelectric conversion element 10 is constructed by the N-type region 122 and the P-type region 123. The diode 121 is constructed by the contact portion 124 and the N-type contact portion 125. The contact portion 124 is connected to the terminal 20. The N-type contact portion 125 is connected to the power voltage terminal 120. As illustrated in FIG. 6, by constructing the diode 121 by the contact portion 124 and the N-type contact portion 125, the current supplying unit 50 can be easily added and an effect of saving a space is obtained.

In FIG. 6, since the contact portion 124 and the N-type contact portion 125 are high-concentration regions, a width of deletion layer in the diode 121 is narrow and a high electric field is applied. A large leak current is generated across the terminals of the diode 121 by an avalanche phenomenon in dependence on the electric field. Therefore, the diode 121 supplies the current to the terminal 20 by the leak current.

By using the diode 121 for supplying the leak current as a current supplying unit 50 as mentioned above, the space saving effect is obtained.

### Third Embodiment

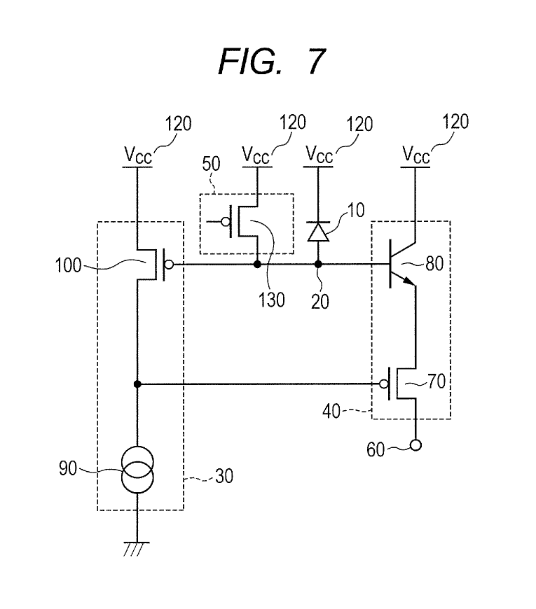

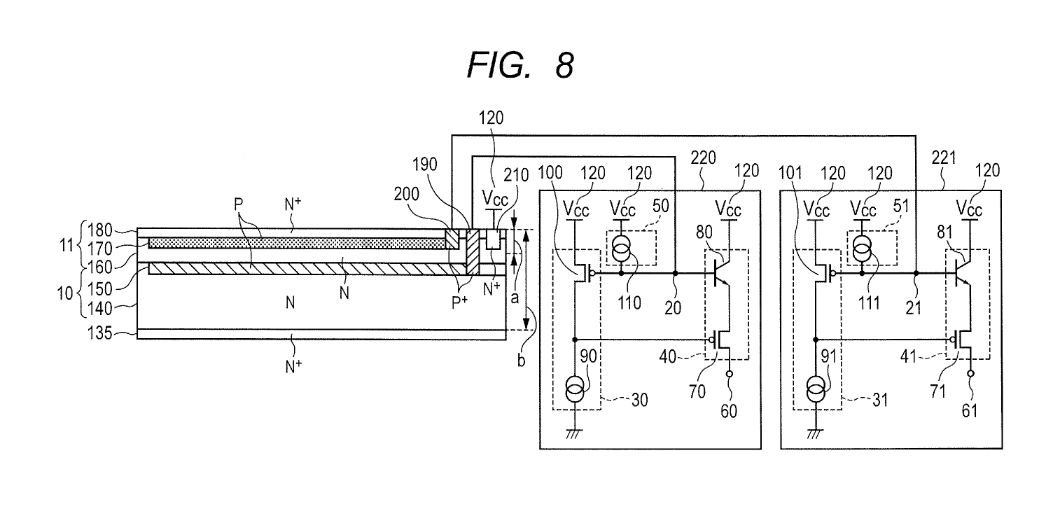

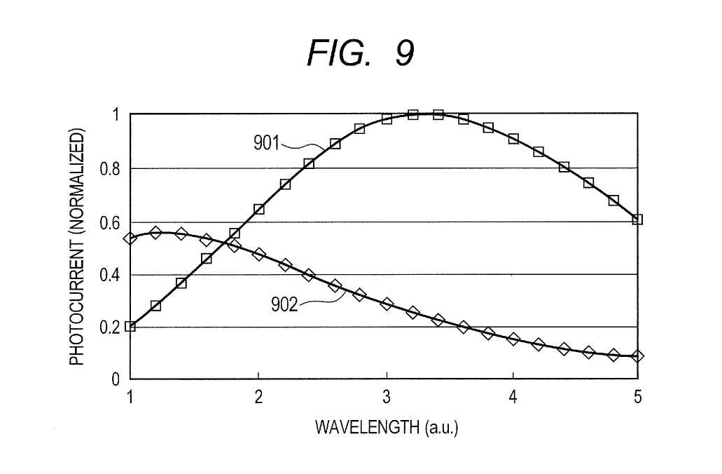

A photoelectric converting apparatus according to the third embodiment will now be described with reference to FIG. 7. The embodiment will be described hereinbelow with respect to only points different from the first embodiment. In FIG. 7, a MOSFET 130 is used as a current supplying unit 50. In the case of detecting the sensor illuminance by using an output current from the current output terminal 60, the MOSFET 130 is turned off or a value of the current which flows is decreased. Thus, an influence of the error current which is superimposed to the photocurrent of the photoelectric conversion element 10 by the MOSFET 130 can be reduced. Explaining furthermore, in the system using the sensor, in the case where the sensor illuminance decreases to a value out of the light amount detecting range of the sensor only at specific timing (for example, in the case where the sensor is light-shielded), it is sufficient to drive the gate potential so that a predetermined current is supplied from the MOSFET 130 only at that time.

For a first period, the current supplying unit 50 supplies the current of a first current value to the terminal 20 of the photoelectric conversion element 10. For a second period, the current supplying unit 50 supplies the current of a second current value smaller than the first current value to the terminal 20 of the photoelectric conversion element 10 or does not supply the current. The first period is a period of time to form a pixel signal. The second period is a period of time to detect the illuminance. As mentioned above, the current supplying unit 50 turns off the current supply to the terminal 20 of the photoelectric conversion element 10 or decreases the supply current in accordance with the operating state of the photoelectric converting apparatus or the light amount, thereby enabling the deterioration in S/N ratio by the error current to be reduced.

### Fourth Embodiment

A photoelectric converting apparatus according to the fourth embodiment will now be described with reference to FIG. 7. The embodiment will be described hereinbelow with respect to only points different from the first embodiment. The embodiment relates to a driving method at the time of turn-on of a power source. In FIG. 7, when the power source is turned on, that is, when a voltage of the power voltage terminal 120 is set from 0V to the power voltage V_{cc}, it takes a long time until the base potential of the bipolar transistor 80 reaches a stationary potential from 0V. This is because it takes a time to charge the parasitic capacitor associated with the base due to the photocurrent. Since the photocurrent is smaller as the luminance is lower, a time is required. It is, therefore, desirable to provide a unit for raising the base potential to a predetermined potential for a predetermined period after the turn-on of the power source. In FIG. 7, by reducing the gate potential of the MOSFET 130 and supplying the larger current for the predetermined period after the turn-on of the power source, such a role can be performed. Consequently, since the unit for raising the base potential can be provided without adding any element, the space saving effect is obtained.

For a first period, the current supplying unit 50 supplies the current of the first current value to the terminal 20 of the photoelectric conversion element 10. For a second period, the current supplying unit 50 supplies the current of the second current value smaller than the first current value to the terminal 20 of the photoelectric conversion element 10 or does not supply the current. The first period is a predetermined period of time after the turn-on of the power source. The second period is a period of time after the first period. As mentioned above, the current supplying unit 50 increases the current supply to the terminal 20 of the photoelectric conversion element 10 at the time of turn-on of the power source, so that the unit for raising the base potential can be provided without adding any element. Therefore, the space saving effect is obtained

### Fifth Embodiment

A photoelectric converting apparatus according to the fifth embodiment will now be described with reference to FIG. 8. The embodiment will be described hereinbelow with respect to only points different from the first embodiment. The embodiment relates to a construction in which the photoelectric conversion elements 10 and 11 are laminated. In FIG. 8, an N-type region 140, a P-type region 150, an N-type region 160, a P-type region 170, and a surface N⁺ region 180 are formed on an N⁺ region 135 in such a manner that the N-type region and the P-type region are alternately laminated. The P-type regions 150 and 170 are formed so as to have different depths. Since light which entered a silicon region intrudes deeper into the layers as a wavelength of the light is longer, photosignals to the light in the different wavelength bands can be obtained from the P-type regions 150 and 170, respectively. In this manner, in FIG. 8, the photoelectric conversion element 10 is formed by the N-type region 140, P-type region 150, and N-type region 160. A photoelectric conversion element 11 is formed by the N-type region 160, P-type region 170, and surface N⁺ region 180. A plurality of photoelectric conversion elements 10 and 11 are laminated in the depth direction. Contact portions 190 and 200 are provided for the P-type regions 150 and 170, thereby reading out the photocurrents from the photoelectric conversion elements 10 and 11, respectively. Reading circuits 220 and 221 are provided for the photoelectric conversion elements 10 and 11, respectively. Each of the reading circuits 220 and 221 has substantially the same construction as the construction excluding the photoelectric conversion element 10 in the photoelectric converting apparatus in FIG. 3. The reading circuits 220 and 221 have detecting units 30 and 31 and have their constant current sources 90 and 91 and MOSFETs 100 and 101, respectively. The reading circuits 220 and 221 have feedback units 40 and 41 and have their MOSFETs 70 and 71 and bipolar transistors 80 and 81, respectively. The reading circuits 220 and 221 also have constant current sources 110 and 111 as current supplying units 50 and 51, respectively. They also have current output terminals 60 and 61, respectively. In FIG. 8, an N-type contact portion 210 is provided in the N-type regions 140 and 160 and the surface N⁺ region 180 and is connected to the power voltage terminal 120. In this manner, in FIG. 8, the reading circuits 220 and 221 are provided for the photoelectric conversion elements 10 and 11, and the current sources 110 and 111 are provided, respectively. Thus, the light response performance and the S/N ratios of the photoelectric conversion elements 10 and 11 can be optimized, respectively.

In FIG. 8, “a” indicates a peak position of an impurity profile in the depth direction of the N-type region 160 and “b” indicates a total thickness of semiconductor layers formed on the N⁺ region 135. In FIG. 8, spectral characteristics of the photoelectric conversion elements 10 and 11 are decided mainly by those two factors “a” and “b”. FIG. 9 illustrates simulation results of the spectral characteristics in the case where “a” and “b” are equal to certain values. In FIG. 9, an axis of abscissa indicates a wavelength of the irradiation light and an axis of ordinate indicates photocurrents which are obtained from the photoelectric conversion elements 10 and 11. Photocurrent characteristics 902 are characteristics of the photoelectric conversion element 11 having a peak at the wavelength 1 position. Photocurrent characteristics 901 are characteristics of the photoelectric conversion element 11 having a peak at the wavelength 3 position. In the case of the spectral characteristics as illustrated in FIG. 9, the photoelectric conversion element 10 can obtain the photocurrent larger than that by the photoelectric conversion element 11 for the light sources of most of the spectral characteristics. Therefore, even if the larger current is set in the current source 110, the similar S/N ratio can be obtained as compared with that in the case of the current source 111. Thus, the current values of the current sources 110 and 111 are individually set and the light response performance and the S/N ratios of the photoelectric conversion elements 10 and 11 can be optimized, respectively. The current supplying unit 50 among the plurality of current supplying units 50 and 51 supplies the current of the current value different from that of at least another current supplying unit 51.

A plurality of combinations each of which is constructed by the photoelectric conversion elements 10 and 11, detecting units 30 and 31, feedback units 40 and 41, and current supplying units 50 and 51 are provided. The plurality of photoelectric conversion elements 10 and 11 are laminated in the depth direction by alternately laminating a plurality of combinations each of which is constructed by the photoelectric converting regions 150 and 170 of the first conductivity type (for example, P type) and the regions 180, 160, and 140 of the second conductivity type (for example, N type) opposite to the first conductivity type. By providing the current supplying units 50 and 51 for the terminals 20 and 21 of the photoelectric conversion elements 10 and 11 laminated in the depth direction, respectively, the light response performance and the S/N ratios of the photoelectric conversion elements 10 and 11 can be optimized, respectively.

### Sixth Embodiment

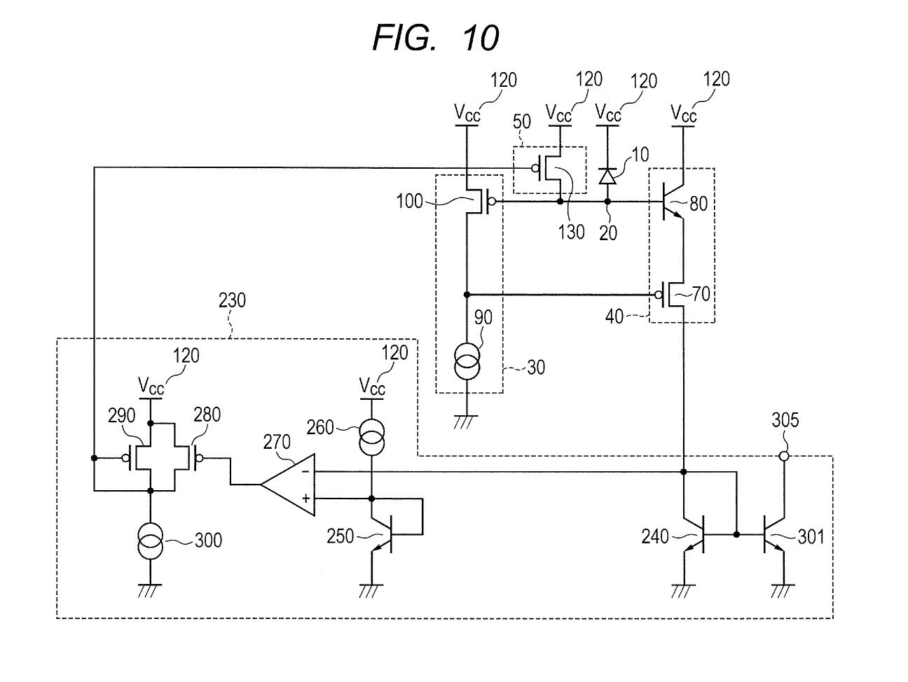

A photoelectric converting apparatus according to the sixth embodiment will now be described with reference to FIG. 10. The embodiment will be described hereinbelow with respect to only points different from the third embodiment. In FIG. 10, a current degradation detecting unit (current detecting unit) 230 is provided. The current degradation detecting unit 230 has bipolar transistors 240 and 250, a current source 260, a comparator 270, MOSFETs 280 and 290, and a current source 300. The current degradation detecting unit 230 also has a bipolar transistor 301 and a current output terminal 305. By controlling a gate potential of the MOSFET 130 by the current degradation detecting unit 230, the driving of the photoelectric converting apparatus can be simplified.

The relation of the equation (1) shown in the first embodiment exists between a base-emitter voltage and a collector current of each of the bipolar transistors 240 and 250. Therefore, when a current of the current source 260 is larger than the drain current of the MOSFET 70, since a non-inverting terminal voltage of the comparator 270 is higher than an inverting terminal voltage, an output of the comparator 270 is set to a power voltage level. Therefore, since the MOSFET 280 is turned off, the gate potential of the MOSFET 130 is set to a bias potential which is decided by a current value of the current source 300 and a size of MOSFET 290. On the contrary, when the current of the current source 260 is smaller than the drain current of the MOSFET 70, since the inverting terminal voltage of the comparator 270 is higher than the non-inverting terminal voltage, the output of the comparator 270 is set to a ground level. Therefore, since the MOSFET 280 is turned on, the gate potential of the MOSFET 130 is high and the drain current of the MOSFET 130 decreases. Since the drain current of the MOSFET 70 is decided by the photocurrent (sensor illuminance) of the photoelectric conversion element 10, when the sensor illuminance is equal to or larger than a predetermined value, the drain current of the MOSFET 130 decreases. Thus, even if the MOSFET 130 is not controlled by a control signal from the outside, for example, when the sensor is light-shielded, the drain current of the MOSFET 130 is automatically increased. In other cases, the drain current of the MOSFET 130 is decreased, thereby enabling the error current to be reduced. Therefore, the driving of the photoelectric converting apparatus can be simplified. The bipolar transistor 301 constructs a current mirror circuit together with the bipolar transistor 240, copies the current which was output from the drain of the MOSFET 70 and outputs from the current output terminal 305.

The current degradation detecting unit (current detecting unit) 230 detects the currents of the current output terminals 60 and 305. A value of the current which is supplied by the current supplying unit 50 changes in accordance with the current which is detected by the current degradation detecting unit 230. By controlling the MOSFET 130 by the current degradation detecting unit 230, the driving of the photoelectric converting apparatus can be simplified.

### Seventh Embodiment

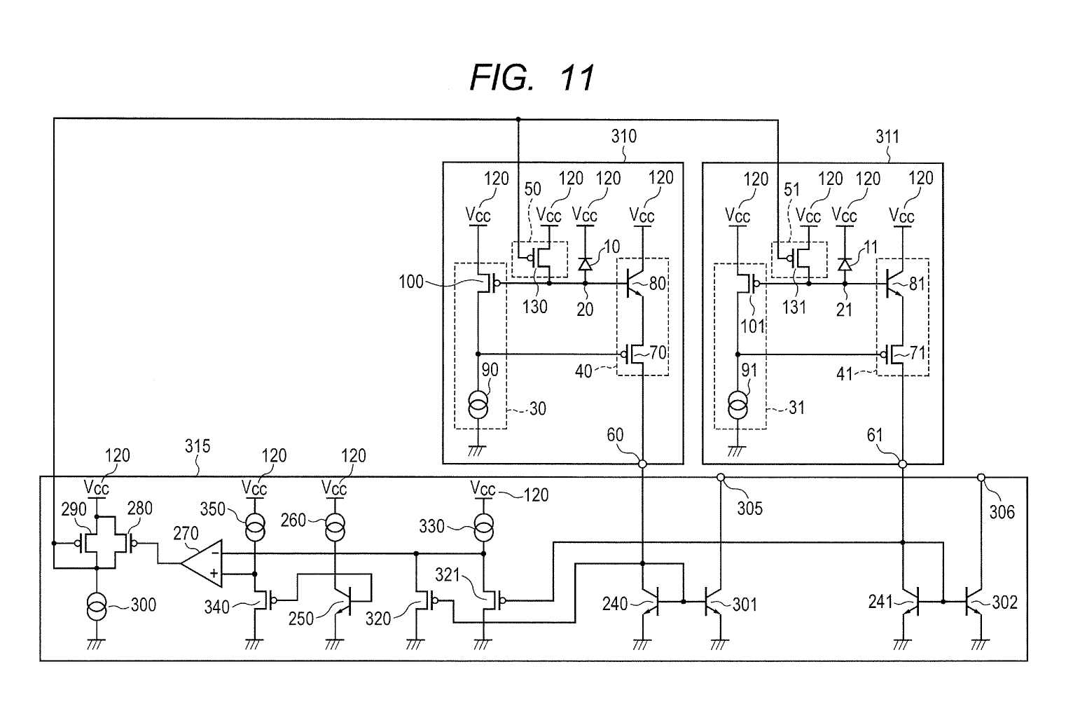

A photoelectric converting apparatus according to the seventh embodiment will now be described with reference to FIG. 11. The embodiment will be described hereinbelow with respect to only points different from the sixth embodiment. In FIG. 11, the apparatus has a plurality of pixels 310 and 311. Each of the pixels 310 and 311 has substantially the same construction as that of the photoelectric converting apparatus in FIG. 7. The pixels 310 and 311 have the photoelectric conversion elements 10 and 11, respectively. The pixels 310 and 311 have the detecting units 30 and 31 and also have their constant current sources 90 and 91 and MOSFETs 100 and 101, respectively. The pixels 310 and 311 also have the feedback units 40 and 41 and have their MOSFETs 70 and 71 and bipolar transistors 80 and 81, respectively. The pixels 310 and 311 have the MOSFETs 130 and 131 as current supplying units 50 and 51 and have their current output terminals 60 and 61, respectively. In FIG. 11, a minimum current detecting unit 315 is provided. The minimum current detecting unit 315 has a construction similar to that of the current degradation detecting unit 230 in FIG. 10 and has bipolar transistors 240 and 241. The unit 315 also has bipolar transistors 301 and 302 and has current output terminals 305 and 306. The unit 315 also has MOSFETs 320 and 321, has a current source 330, and has a MOSFET 340 and a current source 350. In FIG. 11, by controlling the plurality of current supplying units 50 and 51 by the same minimum current detecting unit 315, the space saving effect is obtained.

In FIG. 11, base-emitter voltages of the bipolar transistors 240 and 241 are decided by the output currents from the current output terminals 60 and 61, and gate potentials of the MOSFETs 320 and 321 are determined, respectively. Although the current of the current source 330 is supplied into the MOSFETs 320 and 321, if a difference between the gate potentials of the MOSFETs 320 and 321 is large, the MOSFET of the larger gate potential is turned off because a gate-source voltage is small. Now, an inverting terminal potential of the comparator 270 in the case where the MOSFET 321 is turned off and the gate potential of the MOSFET 320 is set to Vₚ is obtained as follows.

Now, assuming that a current value of the current source 330 is set to Iₐ and is equal to the current flowing in the MOSFET 320, the following expression (7) is satisfied from a drain current of a general MOSFET.

$${I}_{a} \approx \frac{β}{2} {( {V}_{gs} - {V}_{th} )}^{2} \qquad ( 7 )$$

Where, V_{gs} indicates a voltage between the gate and the source of the MOSFET 320 and Vth indicates a threshold voltage.

β is obtained by the following equation (8).

$$β = {μ}_{0} {C}_{ox} \frac{W}{L} \qquad ( 8 )$$

Where, μ₀ indicates a mobility of the carrier, Cₒₓ a gate capacitance per unit area of the MOSFET, W a gate width of the MOSFET, and L a gate length of the MOSFET.

From the expression (7), the voltage V_{gs} is obtained by the following expression (9).

$${V}_{gs} \approx {V}_{th} + \sqrt{\frac{2 {I}_{a}}{β}} \qquad ( 9 )$$

Therefore, an inverting terminal voltage Vₙ of the comparator 270 is obtained by the following expression (10).

$${V}_{n} \approx {V}_{p} + {V}_{th} + \sqrt{\frac{2 {I}_{a}}{β}} \qquad ( 10 )$$

In FIG. 11, when the inverting terminal voltage Vₙ is lower than the non-inverting terminal voltage of the comparator 270, the output of the comparator 270 becomes a power voltage and the MOSFET 280 is turned off. Thus, a bias potential is applied to gates of the MOSFETs 130 and 131. From the expression (9), since the inverting terminal voltage Vₙ is determined by the gate potential Vₚ, when a minimum value of the output currents of the MOSFETs 130 and 131 is lower than a certain value, the bias potential is supplied from the MOSFETs 130 and 131.

A plurality of combinations each of which is constructed by the photoelectric conversion elements 10 and 11, detecting units 30 and 31, feedback units 40 and 41, and current supplying units 50 and 51 are provided. The minimum current detecting unit 315 detects the current of the minimum value between the currents of the plurality of current output terminals 60 and 61. A value of the current which is supplied from each of the plurality of current supplying units 50 and 51 changes in accordance with the current of the minimum value which is detected by the minimum current detecting unit 315. By controlling the plurality of current supplying units 50 and 51 by the same minimum current detecting unit 315 as mentioned above, there is no need to provide the current detecting unit every pixel and the space saving effect is obtained.

The bipolar transistors 301 and 302 construct a current mirror circuit together with the bipolar transistors 240 and 241, respectively. Thus, the currents which were output from drains of the MOSFETs 70 and 71 are copied and output from the current output terminals 305 and 306, respectively.

### Eighth Embodiment

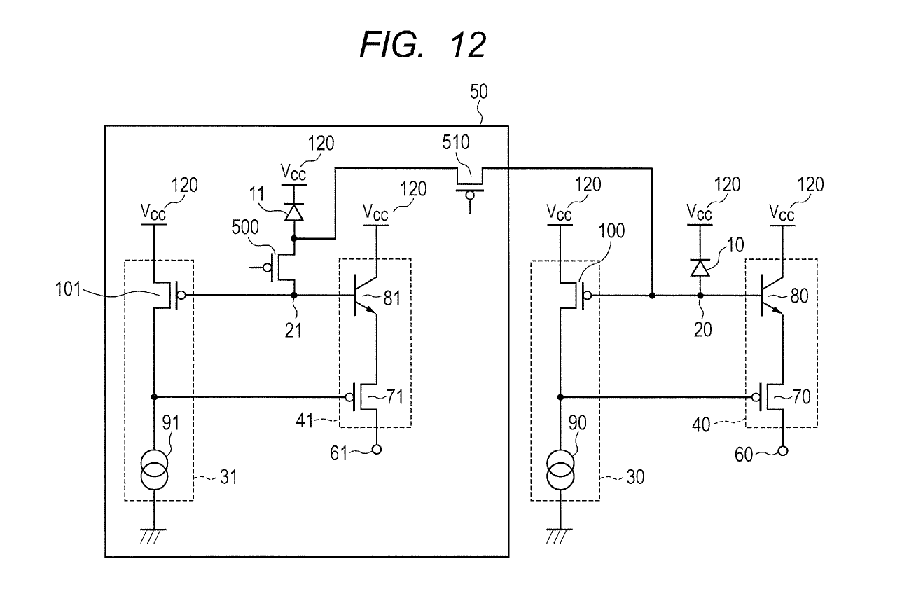

A photoelectric converting apparatus according to the eighth embodiment will now be described with reference to FIG. 12. The embodiment will be described hereinbelow with respect to only points different from the first embodiment and FIG. 8. In FIG. 12, in a manner similar to FIG. 8, the current supplying unit 50 has the second photoelectric conversion element 11, the second terminal 21, the second detecting unit 31, the second feedback unit 41, and MOSFETs 500 and 510. The second photoelectric conversion element 11 is, for example, the second diode and can output a current to the second terminal 21 by the photoelectric conversion. The second detecting unit 31 has the third field effect transistor (MOSFET) 101 and the third current source (constant current source) 91 and detects the electric potential of the second terminal 21. The second feedback unit 41 has the second bipolar transistor 81 and the fourth field effect transistor (MOSFET) 71. The second feedback unit 41 feeds back the signal based on the electric potential detected by the second detecting unit 31 to the second terminal 21 and outputs the current based on the electric potential of the second terminal 21 to the second current output terminal 61. The second terminal 21 is connected to a gate of the MOSFET 101 and a base of the second bipolar transistor 81. A drain of the MOSFET 101 is connected to the third current source 91. A source of the MOSFET 71 is connected to an emitter of the second bipolar transistor 81, a gate is connected to the drain of the MOSFET 101, and a drain is connected to the second current output terminal 61. A drain of the fifth field effect transistor (MOSFET) 500 is connected to the second terminal 21 and a source is connected to an anode of the second photoelectric conversion element (second photodiode). A drain of the sixth field effect transistor (MOSFET) 510 is connected to the anode of the first photoelectric conversion element (first photodiode) 10 and a source is connected to the anode of the second photoelectric conversion element (second photodiode) 11. The MOSFETs 500 and 510 are a current adding unit and output the current to the first terminal 20 of the first photoelectric conversion element 10 by using the current which is generated by the second photoelectric conversion element 11.

In the case where the MOSFET 500 is made operative in the ON state and the MOSFET 510 is made operative in the OFF state, the photocurrents generated by the photoelectric conversion elements 10 and 11 are amplified by the bipolar transistors 80 and 81 and output from the current output terminals 60 and 61, respectively. In this case, when the light irradiated to the photoelectric conversion element 10 changes from the state of the illuminance of the scale −10 of the axis of abscissa in FIG. 1 to the state of the illuminance of 0, the capacitor associated with the terminal 20 is charged by the photocurrent. Therefore, it is necessary to raise the base potential 151 in FIG. 1 from the base potential 151 of the scale −10 to the base potential 151 of the scale 0. A time which is required to such a process is equal to C·ΔV/I when it is assumed that a capacitance associated with the terminal 20 is set to C, a change amount of the base potential 151 is set to ΔV, and the photocurrent of the photoelectric conversion element 10 is set to I, respectively.

On the other hand, in the case where the MOSFET 500 is made operative in the OFF state and the MOSFET 510 is made operative in the ON state, an addition current of the photocurrents generated by the photoelectric conversion elements 10 and 11 is amplified by the bipolar transistor 80 and output from the current output terminal 60. In this case, in a manner similar to that mentioned above, when the light irradiated to the photoelectric conversion elements 10 and 11 changes from the state of the illuminance of the scale −10 of the axis of abscissa in FIG. 1 to the state of the illuminance of 0, the capacitor associated with the terminal 20 is charged by the photocurrents of the photoelectric conversion elements 10 and 11. Therefore, the base potential 151 in FIG. 1 is raised from the base potential 151 of the scale −10 to the base potential 151 of the scale 0. A time which is required to such a process is equal to C·ΔV/2I when it is assumed that a capacitance associated with the terminal 20 is set to C, a change amount of the base potential 151 is set to ΔV, and the photocurrents of both of the photoelectric conversion elements 10 and 11 are set to I, respectively. Consequently, the time which is required to charge can be shortened to ½ of that in the foregoing case. Since an amount of photocurrent which flows into the bipolar transistor 80 is doubled, each of the base potential 151 and the emitter potential 152 in FIG. 1 is shifted to a position where the sensor illuminance is higher by one scale of the axis of abscissa. However, it is not changed by the change amount ΔV of the base potential 151 to the change in sensor illuminance.

By supplying the photocurrent to the terminal 20 from the photoelectric conversion element 11 in the current supplying unit 50 as mentioned above, the light response performance can be improved.

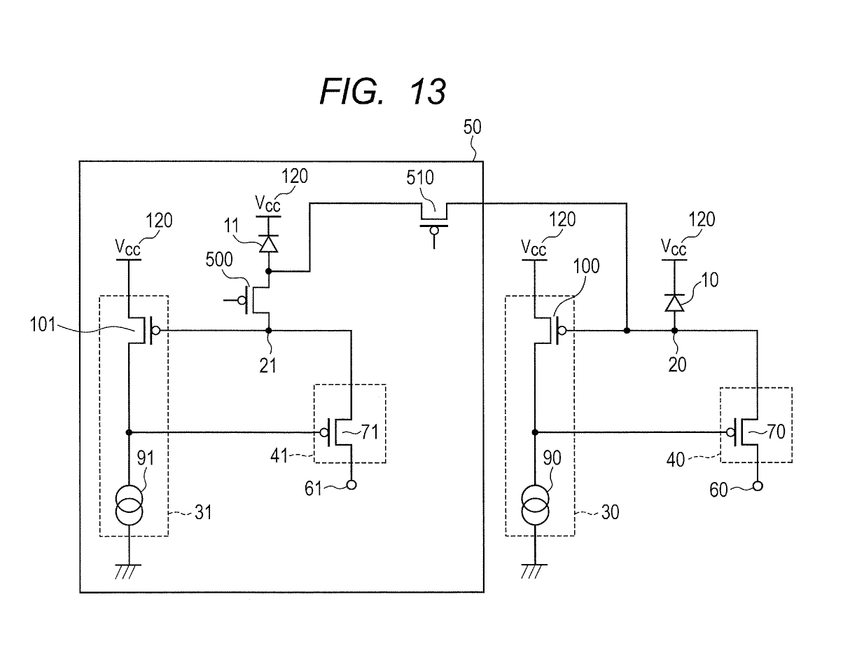

FIG. 13 illustrates an example in the case where the first feedback unit 40 is constructed only by the MOSFET 70 and the second feedback unit 41 is constructed only by the MOSFET 71. The second terminal 21 is connected to the gate of the MOSFET 101 and the source of the MOSFET 71. The drain of the MOSFET 101 is connected to the third current source 91. The gate of the MOSFET 71 is connected to the drain of the MOSFET 101 and a drain is connected to the second current output terminal 61. Also, in this example, the source grounding circuit is constructed by the constant current source 90 and the MOSFET 100 which is driven by it. An anode potential of the photodiode 10 is decided by the gate-source voltage of the MOSFET 100. When the light amount changes, since the current of the MOSFET 70 changes, its source-gate voltage changes. However, the gate potential instead of the anode potential of the photoelectric conversion element 10 fluctuates mainly. The gate potential of the MOSFET 70 which was biased by the current source 90 is made operative instead of the anode which was biased by the photocurrent, thereby improving the light response performance. Also, in this example, the MOSFET 500 is made operative in the OFF state, the MOSFET 510 is made operative in the ON state, and the photocurrent is supplied from the photoelectric conversion element 11, so that the light response performance can be improved.

### Ninth Embodiment

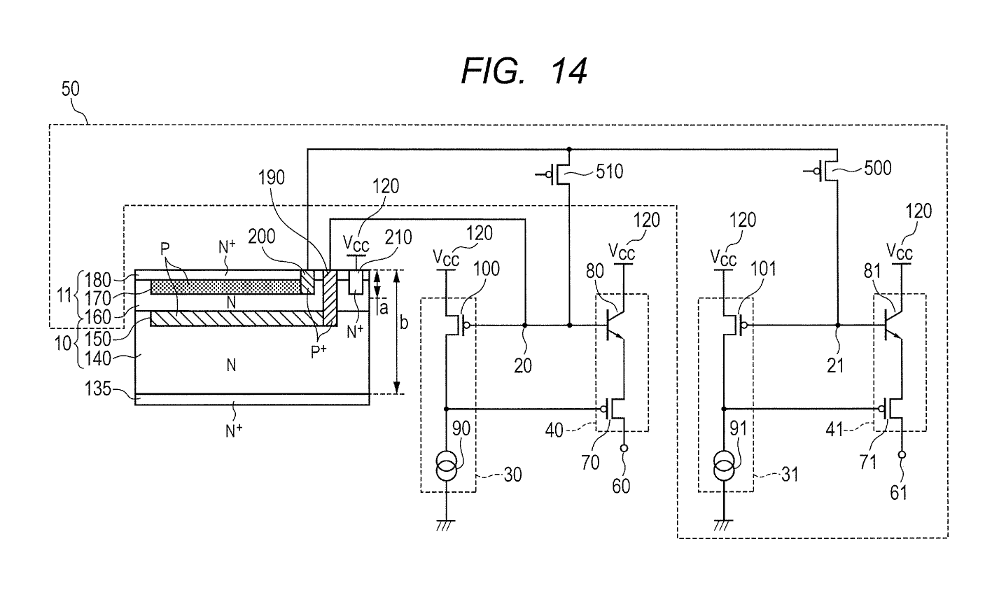

A photoelectric converting apparatus according to the ninth embodiment will now be described with reference to FIG. 14. The embodiment is a combination of the fifth and eighth embodiments. The embodiment will be described hereinbelow with respect to only points different from the fifth and eighth embodiments. In FIG. 14, in a manner similar to FIG. 8, the photoelectric conversion elements 10 and 11 are laminated in the depth direction.

In the case where the MOSFET 500 is made operative in the ON state and the MOSFET 510 is made operative in the OFF state, the photocurrents generated by the photoelectric conversion elements 10 and 11 are amplified by the bipolar transistors 80 and 81 and output from the current output terminals 60 and 61, respectively. Therefore, the photocurrents of different color components can be individually obtained. On the other hand, in the case where the MOSFET 500 is made operative in the OFF state and the MOSFET 510 is made operative in the ON state, the addition current of the photocurrents generated by the photoelectric conversion elements 10 and 11 is amplified by the bipolar transistor 80 and output from the current output terminal 60. At this time, although the number of color components of the photocurrents which are obtained is decreased to one, the light response performance can be improved.

Although the example in which the photocurrents of the photoelectric conversion elements 10 and 11 for obtaining the photocurrents of the different color components are added has been shown in the photoelectric converting apparatus of FIG. 14, the invention is not limited to such an example. For instance, in the case where the apparatus has a plurality of combinations of the photoelectric conversion elements 10 and 11 in FIG. 14, by adding the photocurrents of the photoelectric conversion elements for obtaining the photocurrents of the color components of the same color, the light response performance can be also improved. In this case, each of the first photoelectric conversion element 10 and the second photoelectric conversion element 11 photoelectrically converts the light of the same color component.

### Tenth Embodiment

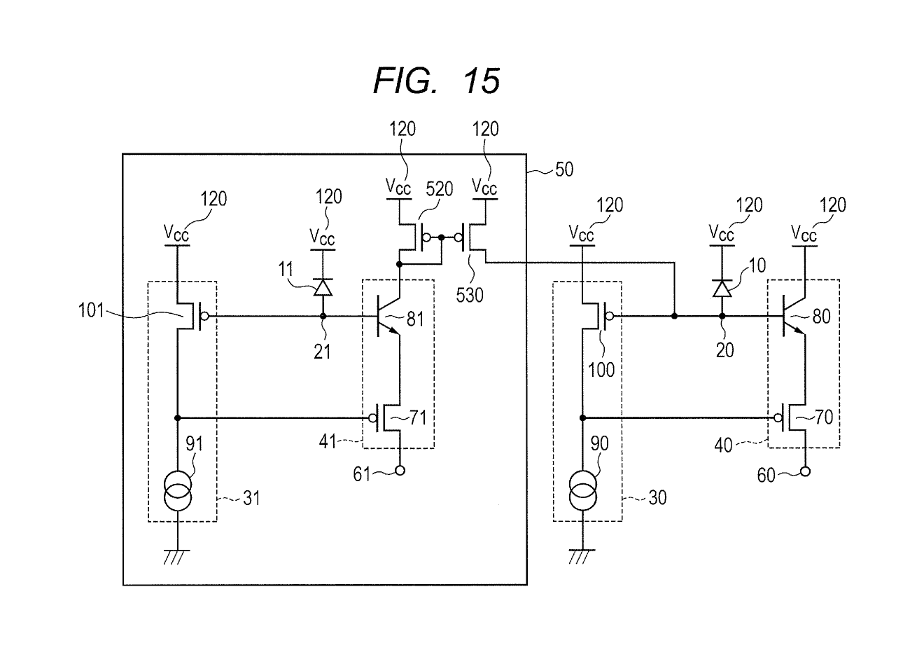

A photoelectric converting apparatus according to the tenth embodiment will now be described with reference to FIG. 15. The embodiment will be described hereinbelow with respect to only points different from the eighth embodiment. In FIG. 15, the current supplying unit 50 further has MOSFETs 520 and 530. A source of the MOSFET 520 is connected to the power voltage terminal 120 and a gate and a drain are connected to a collector of the second bipolar transistor 81. A source of the MOSFET 530 is connected to the power voltage terminal 120, a gate is connected to the gate of the MOSFET 520, and a drain is connected to the terminal 20. The MOSFETs 520 and 530 construct a current mirror circuit.

In FIG. 15, the photoelectric converting apparatus amplifies the photocurrent of the photoelectric conversion element 11 by the bipolar transistor 81 and outputs from the current output terminal 61. At the same time, the photoelectric converting apparatus detects the output current by using the MOSFET 520, forms the current based on the output current by using the MOSFET 530, and supplies to the first terminal 20. The MOSFETs 520 and 530 are a current adding unit and are also a current amplifying unit for amplifying the current which is generated by the second photoelectric conversion element 11 and forming a current to output the current to the first terminal 20 of the first photoelectric conversion element 10. By forming the current which is supplied to the first terminal 20 as mentioned above, the signal current can be also obtained from the second current output terminal 61. That is, the current to charge the capacitor associated with the terminal 20 is increased and the light response performance can be improved.

Now, assuming that the photocurrent of the photoelectric conversion element 11 is set to Iₚ and the current amplification factor of the bipolar transistor 81 is set to hFE, the drain current of the MOSFET 520 is equal to about Iₚ·hFE. At this time, a drain current Id of the MOSFET 530 is obtained by the following expression (11) from the expression (7) and the equation (8).

$${I}_{d} \approx \frac{{β}_{530} \cdot h FE \cdot {I}_{p}}{{β}_{520}} \qquad ( 11 )$$

Where, β₅₂₀ is β of the MOSFET 520 and β₅₃₀ is β of the MOSFET 530.

The capacitor associated with the terminal 20 is charged by using the drain current of the MOSFET 530 in addition to the photocurrent of the photoelectric conversion element 10, so that the light response performance can be improved. However, there is a case where a sensitivity of the second photoelectric conversion element 11 is lower than that of the first photoelectric conversion element 10 and the photocurrent which is generated is small or a capacitance value of the capacitor associated with the second terminal 21 is larger than that of the capacitor associated with the terminal 20. In such a case, since leading of the current of the MOSFET 530 is late, the effect of improvement of the light response performance is not obtained. This is because since the timing of completion of the charging of the second terminal by the photocurrent of the second photoelectric conversion element 11 is later than the timing for charging the first terminal 20 by the photocurrent of the first photoelectric conversion element 10, after the charging of the first terminal 20 was finished, the current of the MOSFET 530 rises. It is, therefore, desirable that the sensitivity of the second photoelectric conversion element is higher than that of the first photoelectric conversion element 10. The sensitivity is proportional to the total number of photocarriers which are obtained when the white light is irradiated. It is also desirable that the capacitance value of the capacitor associated with the second terminal 21 is smaller than that of the capacitor associated with the terminal 20.

In the expression (11), since hFE generally has a value of, for example, about 100, it is desirable to adjust in such a manner that β₅₃₀/β₅₂₀ is set to a value which is equal to or less than 1 and the drain current of the MOSFET 530 does not excessively become large. That is, it is desirable that a current gain of the current amplifying unit of each of the MOSFETs 520 and 530 is equal to or less than 1. This is because since the emitter current of the bipolar transistor 80 is too large and the base-emitter voltage of the bipolar transistor 80 and the gate-source voltage of the MOSFET 70 are too large, an operating voltage range of the circuit is decreased.

### Eleventh Embodiment

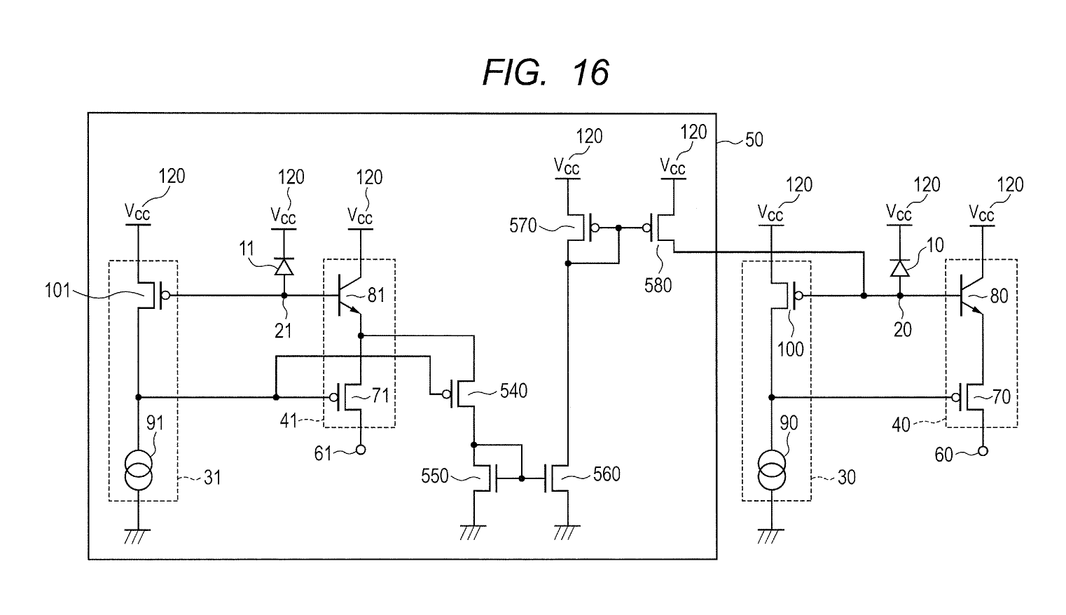

A photoelectric converting apparatus according to the eleventh embodiment will now be described with reference to FIG. 16. The embodiment will be described hereinbelow with respect to only points different from the tenth embodiment. In FIG. 16, the current supplying unit 50 has MOSFETs 540, 550, 560, 570, and 580 in place of the MOSFETs 520 and 530 in FIG. 15. A source of the MOSFET 540 is connected to the emitter of the bipolar transistor 81 and a gate is connected to the gate of the MOSFET 71. A drain and a gate of the MOSFET 550 are connected to a drain of the MOSFET 540 and a source is connected to the ground terminal. A source of the MOSFET 570 is connected to the power voltage terminal 120 and a gate and a drain are connected to a drain of the MOSFET 560. A source of the MOSFET 580 is connected to the power voltage terminal 120, a gate is connected to the gate of the MOSFET 570, and a drain is connected to the terminal 20. A gate of the MOSFET 560 is connected to the gate of the MOSFET 550 and a source is connected to the ground terminal. The MOSFETs 550 and 560 construct a current mirror circuit. The MOSFETs 570 and 580 construct a current mirror circuit.

In FIG. 16, the photoelectric converting apparatus amplifies the photocurrent of the photoelectric conversion element 11 by the bipolar transistor 81, outputs a part of the photocurrent from the current output terminal 61, and forms a current which is output to the terminal 20 by using another part of the photocurrent. By forming the current which is supplied to the terminal 20 as mentioned above, the operating voltage range of the circuit of the bipolar transistor 81 can be improved.

Now, assuming that the photocurrent of the photoelectric conversion element 11 is set to Iₚ and the current amplification factor of the bipolar transistor 81 is set to hFE, the total of the drain currents of the MOSFETs 71 and 540 is equal to about Iₚ·hFE. At this time, since the gate-source voltage of the MOSFET 71 and that of the MOSFET 540 are equal, from the expression (7) and the equation (8), if β of the MOSFETs 71 and 540 are equal, the drain currents of the MOSFETs 71 and 540 are equal. That is, each drain current is equal to Iₚ·hFE/2. Therefore, the current of Iₚ·hFE/2 is output from the current output terminal 61. By using the current of Iₚ·hFE/2 of the MOSFET 540, each of the MOSFETs 550, 560, 570, and 580 forms the current which is output to the terminal 20. From the expression (7) and the equation (8), the drain current Id which is output from the MOSFET 580 is obtained by the following expression (12).

$${I}_{d} \approx \frac{{β}_{560} \cdot {β}_{580} \cdot {I}_{p}}{2 {β}_{550} \cdot {β}_{570}} \qquad ( 12 )$$

Where, β₅₅₀, β₅₆₀, β₅₇₀, and β₅₈₀ are β of the MOSFETs 550, 560, 570, and 580, respectively. The capacitor associated with the terminal 20 is charged by using the drain current of the MOSFET 580 in addition to the photocurrent of the photodiode 10, so that the light response performance can be improved. When comparing with FIG. 15, it will be understood that the collector potential of the bipolar transistor 81 in FIG. 16 is higher by an amount of the gate-source voltage of the MOSFET 520 in FIG. 15. In order to make the bipolar transistor 81 operative in an active region, it is necessary that the collector and the base have inversely been biased. An upper limit of the base potential is limited by the collector potential. Therefore, the base potential can be set so as to be higher by an amount of the high collector potential of the bipolar transistor 81. The operating voltage range of the circuit can be improved.

### Twelfth Embodiment

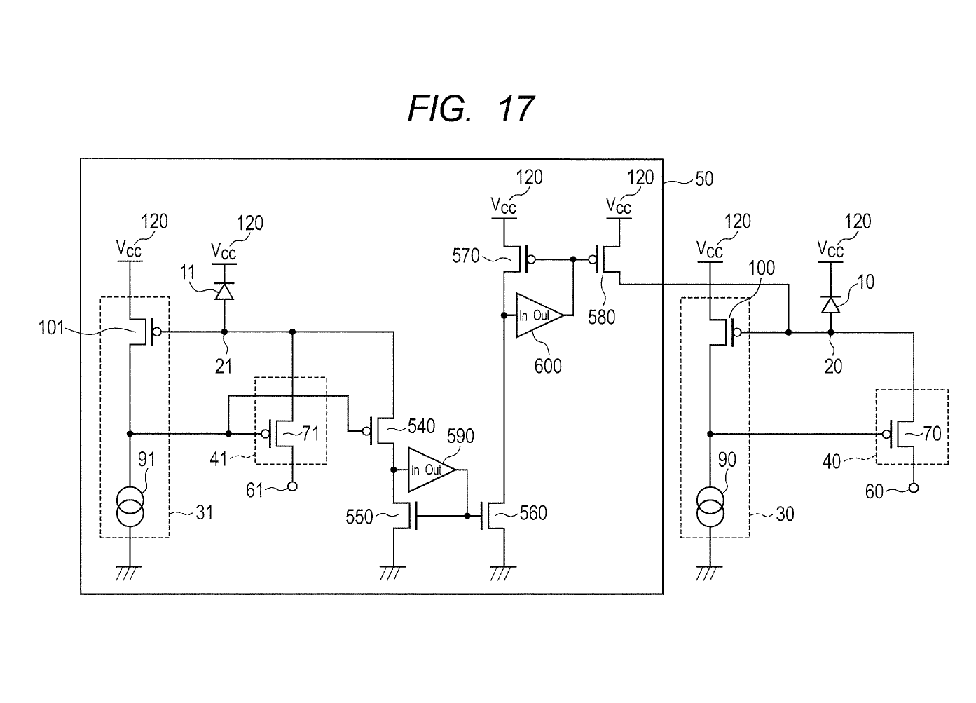

A photoelectric converting apparatus according to the twelfth embodiment will now be described with reference to FIG. 17. The embodiment will be described hereinbelow with respect to only points different from the eleventh embodiment. In FIG. 17, the feedback units 40 and 41 do not have the bipolar transistors 80 and 81, respectively. The current supplying unit 50 further has voltage buffers 590 and 600. An input terminal of the voltage buffer 590 is connected to the drain of the MOSFET 550 and an output terminal is connected to the gate of the MOSFET 550. An input terminal of the voltage buffer 600 is connected to the drain of the MOSFET 570 and an output terminal is connected to the gate of the MOSFET 570. By the voltage buffers 590 and 600, the time which is required to charge the capacitor associated with the gate of each of the MOSFETs 550, 560, 570, and 580 is shortened and the light response performance can be improved.

In FIG. 17, the photoelectric converting apparatus outputs a part of the photocurrent of the photoelectric conversion element 11 from the current output terminal 61 and forms a current which is output to the terminal 20 by using another part of the photocurrent. Assuming that the photocurrent of the photoelectric conversion element 11 is set to Iₚ, the total of the drain currents of the MOSFETs 71 and 540 is equal to Iₚ. At this time, if β of the MOSFETs 71 and 540 are equal, the drain currents of the MOSFETs 71 and 540 are equal and are set to Iₚ/2. If the voltage buffer 590 is absent, the capacitor associated with the gate of each of the MOSFETs 550 and 560 is charged by such a current. When the photocurrent Iₚ is very small, since it takes a time to charge, the leading of the drain current of the MOSFET 560 is late and the leading of the drain current of the MOSFET 580 is late, thereby obstructing the improvement of the light response performance. Therefore, by providing the voltage buffer 590 and driving the capacitor associated with the gate of each of the MOSFETs 550 and 560, the capacitance value of the capacitor which is charged by the drain current of the MOSFET 540 is decreased, so that the light response performance can be improved.

The larger the drain current of the MOSFET 580 in the expression (12) is, the larger effect of improvement of the light response performance can be obtained. Therefore, it is desirable that β₅₆₀·β₅₈₀/β₅₅₀·β₅₇₀ is set to 1 or more and the current is amplified and output. The MOSFETs 540, 550, 560, 570, and 580 and the voltage buffers 590 and 600 are a current adding unit and is a current amplifying unit for amplifying the current which is generated by the second photoelectric conversion element 11, forming a current to output the current to the first terminal 20 of the first photoelectric conversion element 10. It is desirable that a current gain of the current amplifying unit of the MOSFETs 550, 560, 570, and 580 is equal to or larger than 1.

### Thirteenth Embodiment

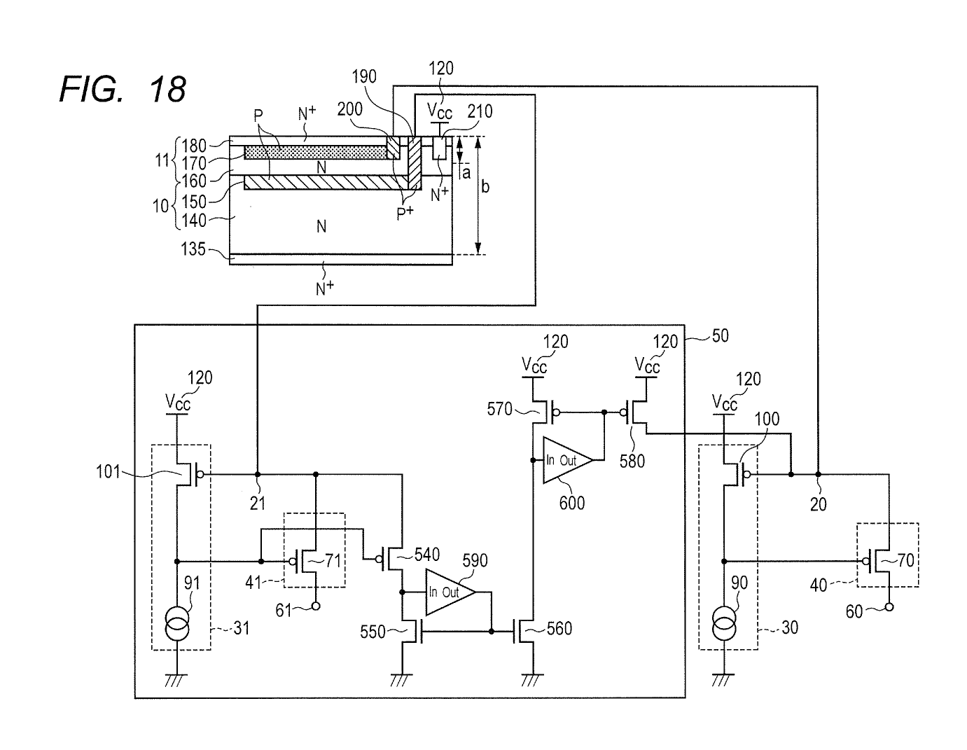

A photoelectric converting apparatus according to the thirteenth embodiment will now be described with reference to FIG. 18. The embodiment will be described hereinbelow with respect to only points different from the ninth and twelfth embodiments. In FIG. 18, as compared with FIG. 17, it differs with respect to a point that the photoelectric conversion elements 10 and 11 are laminated in the depth direction in a manner similar to FIG. 8.

The photoelectric converting apparatus in FIG. 18 outputs a part of the photocurrent of the photoelectric conversion element 10 from the current output terminal 61 and forms a current which is output to the terminal 20 by using another part of the photocurrent, thereby improving the light response performance. An addition current of the drain current of the MOSFET 580 based on the photocurrent of the photoelectric conversion element 10 and the photocurrent of the photoelectric conversion element 11 is output from the current output terminal 60. Thus, an output current having the photocurrent characteristics 901 in FIG. 9 can be obtained from the current output terminal 61. An output current having the photocurrent characteristics in which a component proportional to the photocurrent characteristics 901 in FIG. 9 and the photocurrent characteristics 902 have been added can be obtained from the current output terminal 60. Therefore, as compared with the photoelectric converting apparatus in FIG. 14, according to the photoelectric converting apparatus in FIG. 18, while the output currents having the two different color components can be simultaneously obtained from the current output terminals 60 and 61, the current for charging the terminal 20 is increased and the light response performance can be improved.

By executing a proper differencing process to the output current from the first current output terminal 60 by using the output current from the second current output terminal 61, the signal component of the photocurrent characteristics 901 is removed and a signal having the photocurrent characteristics 902 can be obtained. That is, the differencing process is executed by using the signal based on the current which is obtained from the first current output terminal 60 and the signal based on the current which is obtained from the second current output terminal 61.

In the foregoing first to thirteenth embodiments, the case where the elements of such a type that holes are collected are used as photoelectric conversion elements 10 and 11 has been described. However, the invention is not limited to such an example. Even in the case where the elements of such a type that electrons are collected are used as photoelectric conversion elements 10 and 11, by using a construction similar to that mentioned above, a similar effect can be obtained.

In the foregoing first to thirteenth embodiments, although the case where the source grounding circuit is used as a detecting unit 30 has been described. However, the invention is not limited to such an example.

In the foregoing first to thirteenth embodiments, although the case where the bipolar transistor 80 and the MOSFET 70 are used as a first feedback unit 40 has been described as an example, the invention is not limited to such an example.

In the foregoing first to seventh embodiments, although the case where the current source 110, diode 121, or MOSFET 130 is used as a current supplying unit 50 has been described as an example, the invention is not limited to such an example.

In the foregoing fifth, ninth, and thirteenth embodiments, although the case where the number of photoelectric conversion elements 10 and 11 which were laminated in the depth direction is set to 2 has been described as an example, the invention is not limited to such an example.

In the foregoing sixth embodiment, the current degradation detecting unit 230 is not limited to the unit illustrated in FIG. 10.

In the foregoing seventh embodiment, the minimum current detecting unit 315 is not limited to the unit illustrated in FIG. 11.

The foregoing embodiments have merely been shown as specific examples upon embodying the invention and their technical scopes should not be limitatively interpreted by them. That is, the invention can be embodied in various forms without departing from its technical idea or its principal features.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application Nos. 2011-263704, filed Dec. 1, 2011, and 2012-203185, filed Sep. 14, 2012 which are hereby incorporated by reference herein in their entirety.

What is claimed is:

1. A photoelectric converting apparatus comprising:
a first photoelectric conversion element for outputting a current to a first terminal by a photoelectric conversion;
a first detecting unit configured to detect an electric potential of the first terminal of the first photoelectric conversion element;
a first feedback unit configured to feed back a signal based on the electric potential detected by the first detecting unit to the first terminal of the first photoelectric conversion element and output a current based on the electric potential of the first terminal of the first photoelectric conversion element to a first current output terminal; and
a current supplying unit configured to supply an current to the first terminal of the first photoelectric conversion element.

2. The apparatus according to claim 1, wherein:
the first photoelectric conversion element is a first photodiode;
the first terminal of the first photoelectric conversion element is an anode of the first photodiode;
the first detecting unit has a first field effect transistor and a first current source;
the first feedback unit has a first bipolar transistor and a second field effect transistor;
the anode of the first photodiode is connected to a gate of the first field effect transistor and a base of the first bipolar transistor;
a drain of the first field effect transistor is connected to the first current source; and
a source of the second field effect transistor is connected to an emitter of the first bipolar transistor, a gate is connected to a drain of the first field effect transistor, and a drain is connected to the first current output terminal.

3. The apparatus according to claim 1, wherein for a first period, the current supplying unit supplies the current of a first current value to the first terminal of the first photoelectric conversion element, and for a second period, the current supplying unit supplies the current of a second current value smaller than the first current value to the first terminal of the first photoelectric conversion element or does not supply the current.

4. The apparatus according to claim 3, wherein:
the first period is a period for forming a pixel signal; and
the second period is a period for detecting an illuminance.

5. The apparatus according to claim 3, wherein:
the first period is a predetermined period after a power source was turned on; and
the second period is a period after the first period.

6. The apparatus according to claim 1, wherein:
a plurality of combinations each of which is constructed by the first photoelectric conversion element, the first detecting unit, the first feedback unit, and the current supplying unit are provided; and
the plurality of first photoelectric conversion elements are laminated in a depth direction by alternately laminating a plurality of sets each of which is constructed by a photoelectric converting region of a first conductivity type and a region of a second conductivity type opposite to the first conductivity type.

7. The apparatus according to claim 6, wherein one of the plurality of current supplying units supplies the current of a current value different from that of at least another one of the current supplying units.

8. The apparatus according to claim 1, further comprising a current detecting unit configured to detect the current of the first current output terminal, and
wherein a value of the current which is supplied by the current supplying unit changes in accordance with the current which is detected by the current detecting unit.

9. The apparatus according to claim 1, wherein:
a plurality of combinations each of which is constructed by the first photoelectric conversion element, the first detecting unit, the first feedback unit, and the current supplying unit are provided;
the apparatus further comprises a minimum current detecting unit configured to detect the current of a minimum value among the currents of the plurality of first current output terminals; and
a value of the current which is supplied by each of the plurality of current supplying units changes in accordance with the current of the minimum value which is detected by the minimum current detecting unit.

10. The apparatus according to claim 1, wherein the current supplying unit has:
a second terminal;
a second photoelectric conversion element which can output the current to the second terminal by a photoelectric conversion;
a second detecting unit configured to detect an electric potential of the second terminal;
a second feedback unit configured to feed back a signal based on the electric potential detected by the second detecting unit to the second terminal and output a current based on the electric potential of the second terminal to a second current output terminal; and
a current adding unit configured to output the current to the first terminal of the first photoelectric conversion element by using the current which is generated by the second photoelectric conversion element.

11. The apparatus according to claim 10, wherein the current adding unit has a current amplifying unit configured to amplify the current which is generated by the second photoelectric conversion element and output the current to the first terminal of the first photoelectric conversion element.

12. The apparatus according to claim 11, wherein a sensitivity of the second photoelectric conversion element is higher than a sensitivity of the first photoelectric conversion element.

13. The apparatus according to claim 10, wherein the first and second photoelectric conversion elements are laminated in a depth direction by alternately laminating a plurality of sets each of which is constructed by a photoelectric converting region of a first conductivity type and a region of a second conductivity type opposite to the first conductivity type.

14. The apparatus according to claim 13, wherein a differencing process is executed by using a signal based on the current which is obtained from the first current output terminal and a signal based on the current which is obtained from the second current output terminal.
